(19) United States
(12) Patent Application Publication
(10) Pub. No.: US 2025/0221226 A1
(43) Pub. Date: Jul. 3, 2025

(54) Thin Film Transistor Substrate and Display Device Using the Same

(71) Applicant: LG Display Co., Ltd., Seoul (KR)

(72) Inventors: JiYoung Ahn, Paju-si (KR); Ahnki Kim, Paju-si (KR)

(21) Appl. No.: 18/945,252

(22) Filed: Nov. 12, 2024

(30) Foreign Application Priority Data
Dec. 29, 2023 (KR) 10-2023-0197821

(51) Int. Cl. H10K 59/38; H10K 59/121; H10K 59/80

(52) U.S. Cl. CPC H10K 59/38; H10K 59/1213; H10K 59/873; H10K 59/8792

(57) ABSTRACT

Disclosed is a transparent display device comprising a first substrate including a display area and a transmissive area, a first sub-pixel and a second sub-pixel disposed on the display area, a first color filter disposed in the display area and corresponding to the first sub-pixel, and a first color compensation layer disposed in the transmissive area.

### CROSS-REFERENCE TO RELATED APPLICATION

This application claims the benefit of the Republic of Korea Patent Application No. 10-2023-0197821 filed on Dec. 29, 2023, which is hereby incorporated by reference in its entirety.

### BACKGROUND

### Technical Field

The present disclosure relates to a transparent display device.

### Description of the Related Art

As an information society develops, demands for a display device for displaying an image are increasing in various forms. Accordingly, various display devices such as a liquid crystal display (LCD), a plasma display (PDP), and an organic light emitting display (OLED) have recently been used.

Among the display devices, the organic light emitting display device is a self-emission type and has excellent viewing angle and contrast ratio compared to the liquid crystal display (LCD). In addition, since a separate backlight is not required, light weight and thinness are possible, and power consumption is advantageous. Furthermore, the organic light emitting display device has advantages of being able to drive a DC low voltage, a fast response speed, and particularly low manufacturing cost.

An organic light emitting display device has a structure in which an organic light emitting device including a light emitting layer is provided between a cathode for injecting electrons and an anode for injecting holes. An organic light emitting display device is a display device using the principle that when electrons generated from a cathode and holes generated from an anode are injected into an emission layer, the injected electrons and holes are combined to generate excitons, and the generated excitons fall from an excited state to a ground state and emit light.

By applying a transparent display panel, the transparent display device can improve aesthetics because it can be seen through the back like a general glass when the display device is not driven, and has a wide range of fields used and applied in various fields such as a display provided in a vehicle window and a display used in home appliances.

Meanwhile, a plurality of insulating layers, light emitting layers, and transparent electrodes may be provided in the transmissive area representing the transparent portion of the transparent display panel so that light passing through the transmissive area may turn yellowish. In this case, a problem of deteriorating visibility of the transparent display panel may occur.

### SUMMARY

The present disclosure has been made in view of the above problems, and it is an object of the present disclosure to provide a transparent display device in which a color compensation layer is provided in the transmissive area to prevent or at least reduce light passing through the transmissive area from becoming yellowish.

In accordance with an aspect of the present disclosure, the above and other objects can be accomplished by the provision of a transparent display device comprising: a first substrate including a display area that display an image and a transmissive area that is more transmissive of light than the display area; a first sub-pixel and a second sub-pixel in the display area; a first color filter in the display area, the first color filter overlapping the first sub-pixel; and a first color compensation layer in the transmissive area, the first color compensation layer filters light of a predetermined color that passes through the transmissive area.

Furthermore, the above and other objects can be accomplished by the provision of a transparent display device comprising: a first pixel area including a first sub-pixel to a fourth sub-pixel of the first pixel area; a second pixel area including a first sub-pixel to a fourth sub-pixel of the second pixel area; a first transmissive area between the first pixel area and the second pixel area; and a first color compensation layer in the first transmissive area, wherein the first color compensation layer has a transmittance of light in in a first wavelength range not less than 380 nm and less than 500 nm that is greater than a transmittance of light in a second wavelength range from 500 nm to 780 nm, and the transmittance of light in the second wavelength range at least 80%.

In one embodiment, A transparent display device comprising: a first substrate including a display area that display an image and a transmissive area that is more transmissive of light than the display area; a first transistor in the display area; a first light emitting element in the display area, the first light emitting element connected to the first transistor; a color filter in the display area, the color filter overlapping the first light emitting element; and a first color compensation layer in the transmissive area, the first color compensation layer on a same plane as the color filter.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a perspective view schematically illustrating a transparent display device according to an embodiment of the present disclosure.

FIG. 2 is a plan view schematically showing a transparent display device according to an embodiment of the present disclosure.

FIG. 3 is a plan view of an enlarged view of an area A of FIG. 2 according to an embodiment of the present disclosure.

FIG. 4 is a cross-sectional view I-I′ of FIG. 1 according to an embodiment of the present disclosure.

FIG. 5 is a graph illustrating a transmittance according to a wavelength of a color compensation layer of a transparent display device according to an embodiment of the present disclosure.

FIG. 6 is a plan view of an enlarged view of an area A of FIG. 2 according to another embodiment of the present disclosure.

FIG. 7 is a plan view of an enlarged view of an area A of FIG. 2 according to another embodiment of the present disclosure.

FIG. 8 is a cross-sectional view II-II′ of FIG. 6 according to another embodiment of the present disclosure.

FIG. 9 is a table comparing a transparent display device according to another embodiment of the present disclosure with a transparent display device according to a comparative example.

FIG. 10 is a cross-sectional view II-II′ of FIG. 6 according to another embodiment of the present disclosure.

FIG. 11 is a plan view of an enlarged view of an area A of FIG. 2 according to another embodiment of the present disclosure.

FIG. 12 is a cross-sectional view III-III′ of FIG. 11 according to another embodiment of the present disclosure.

### DETAILED DESCRIPTION

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art. Further, the present disclosure is only defined by the scope of the claims.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically The embodiments of the present disclosure may be carried out independently from each other, or may be carried out together in a co-dependent relationship.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode may be the drain electrode, and the drain electrode may be the source electrode. Also, the source electrode in any one embodiment of the present disclosure may be the drain electrode in another embodiment of the present disclosure, and the drain electrode in any one embodiment of the present disclosure may be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region may be a source electrode, and a drain region may be a drain electrode. Also, a source region may be a drain electrode, and a drain region may be a source electrode.

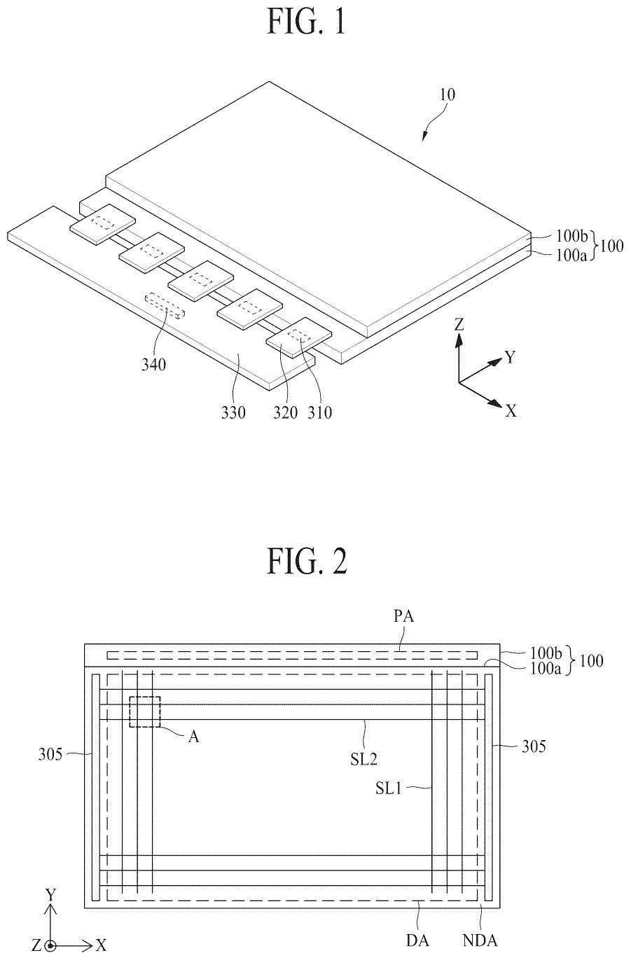

FIG. 1 is a perspective view schematically illustrating a transparent display device according to an embodiment of the present disclosure, and FIG. 2 is a plan view schematically showing a transparent display device according to an embodiment of the present disclosure.

Hereinafter, the X axis represents a direction parallel to the scan line, the Y axis represents a direction parallel to the data line, and the Z axis represents the height direction of the transparent display device 10.

Although the transparent display device 10 according to an embodiment of the present disclosure is mainly described as an organic light emitting transparent display, it may be implemented as a liquid crystal display LCD, a plasma display panel PDP, a quantum dot light emitting display QLED, or an electrophoretic transparent display.

Referring to FIGS. 1 and 2, a transparent display device 10 according to an embodiment of the present disclosure includes a display panel 100, a source drive integrated circuit (hereinafter referred to as an “IC”) 310, a flexible film 320, a circuit board 330, and a timing controller 340.

The display panel 100 may include the first substrate 100a and the second substrate 100b facing each other. The second substrate 100b may be an encapsulation substrate. The first substrate 100a may be a plastic film, a glass substrate of a silicon wafer substrate formed by using a semiconductor process. The second substrate 100b may be a plastic film, a glass substrate, or an encapsulation film. The first substrate 100a and the second substrate 100b may be made of a transparent material.

The display panel 100 may be divided into a display area DA in which pixels are formed to display an image and a non-display area NDA in which an image is not displayed.

First signal lines SL1, second signal lines SL2, and pixels may be provided in the display area DA, and a pad area PA in which pads are disposed and at least one gate driver 305 may be provided in the non-display area NDA.

The first signal lines SL1 may extend in a first direction, for example a Y axis direction, and may cross the second signal lines SL2 in the display area DA. The second signal lines SL2 may extend in a second direction, for example an X axis direction in the display area DA. The pixels are provided in an area in which the first signal line SL1 is provided or an area in which the first signal line SL1 and the second signal line SL2 intersect, and emit predetermined light to display an image.

The source drive IC 310 receives digital video data and a source control signal from the timing controller 340. The source drive IC 310 converts digital video data into analog data voltages according to a source control signal and supplies the converted analog data voltages to the data lines. When the source drive IC 310 is manufactured as a driving chip, the source drive IC 310 may be mounted on the flexible film 320 in a chip on film (COF) or chip on plastic (COP) manner.

Wirings connecting pads and the source drive IC 310 and wirings connecting pads and wirings of the circuit board 330 may be formed in the flexible film 320. The flexible film 320 is attached onto the pads using an anisotropic conducting film, and thus the wirings of the pads and the flexible film 320 may be connected to each other.

The circuit board 330 may be attached to the flexible films 320. A plurality of circuits implemented with driving chips may be mounted on the circuit board 330. For example, the timing controller 340 may be mounted on the circuit board 330. The circuit board 330 may be a printed circuit board or a flexible printed circuit board.

The timing controller 340 receives digital video data and a timing signal from an external system board (not shown). The timing controller 340 generates a gate control signal for controlling the operation timing of the gate driver 305 and a source control signal for controlling the source drive ICs 310, based on the timing signal. The timing controller 340 supplies the gate control signal to the gate driver 305, and supplies the source control signal to the source drive ICs 310.

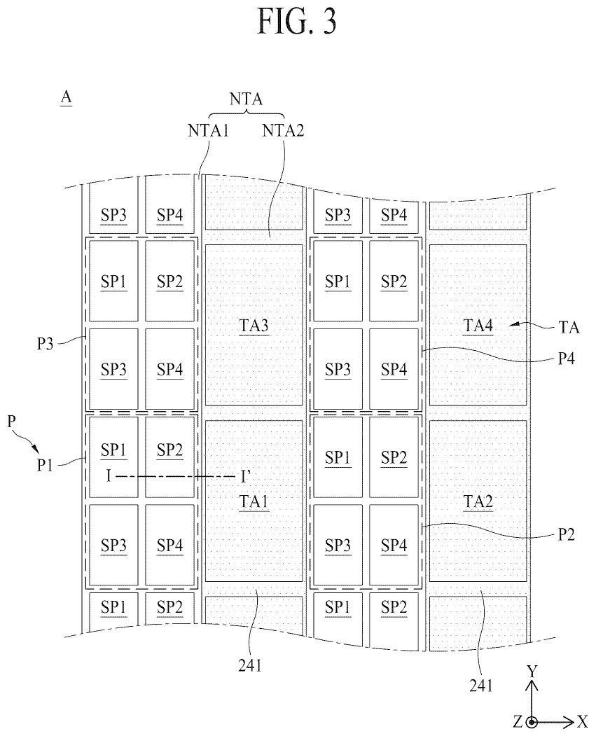

FIG. 3 is a plan view of a transparent display device according to an embodiment of the present disclosure. In this case, FIG. 3 is an enlarged view of an area A of FIG. 2.

As shown in FIG. 3, the transparent display device according to an embodiment of the present disclosure includes a plurality of pixel areas P, a non-transmissive area NTA, a plurality of transmissive areas TA, and a first color compensation layer 241.

The plurality of transmissive areas TA are areas through which most of the light incident from the outside passes, and the non-transmissive area NTA and the plurality of pixel areas P are areas through which most of the light incident from the outside is not transmitted. In this case, the light transmittance in the plurality of transmissive areas TA may be higher than that in the non-transmissive area NTA and the plurality of pixel areas P. Since the display panel 100 includes the plurality of transmissive areas TA, an object or a background positioned on the rear surface of the display panel 100 (see FIG. 1) may be visually recognized.

The plurality of transmissive areas TA includes, for example, the first transmissive area TA1, the second transmissive area TA2, the third transmissive area TA3, and the fourth transmissive area TA4. In this case, the first transmissive area TA1 and the third transmissive area TA3 are arranged in the first direction, for example, the Y direction, and the second transmissive area TA2 and the fourth transmissive area TA4 may be spaced apart from the first transmissive area TA1 and the third transmissive area TA3 in the second direction, for example, the X direction, and may be arranged in the first direction.

The first transmissive area TA1 may be provided between the first pixel area P1 and the second pixel area P2, and the third transmissive area TA3 may be provided between the third pixel area P3 and the fourth pixel area P4.

The area of each of the transmissive areas TA1, TA2, TA3, and TA4 may be larger than the area of any one of the sub-pixels SP1, SP2, SP3, and SP4 provided in each of the pixel areas P1, P2, P3, and P4.

The plurality of pixel areas P may be provided between the plurality of transmissive areas TA. The plurality of pixel areas P may include, for example, a first pixel area P1, a second pixel area P2, a third pixel area P3, and a fourth pixel area P4, and each of the pixel areas P1, P2, P3, and P4 may be provided between the plurality of transmissive areas TA to emit light.

Each of the plurality of pixel areas P may include the first sub-pixel SP1 to the fourth sub-pixel SP4 in which a light emitting element is disposed to emit light. For example, the first pixel area P1, the second pixel area P2, the third pixel area P3, and the fourth pixel area P4 are included, and the first pixel area P1 to the fourth pixel area P4 each include a first sub-pixel SP1 to a fourth sub-pixel SP4, respectively.

The first sub-pixel SP1 emits light of a first color, the second sub-pixel SP2 emits light of a second color, the third sub-pixel SP3 emits light of a third color, and the fourth sub-pixel SP4 emits light of a fourth color. Each of the first sub-pixel SP1 to the fourth sub-pixel SP4 may emit light of a different color. For example, the first sub-pixel SP1 may emit light of red color, the second sub-pixel SP2 may emit light of white color, the third sub-pixel SP3 may emit light of green color, and the fourth sub-pixel SP4 may emit light of blue color. Meanwhile, the present disclosure is not limited thereto, and a color of light emitted by each of the sub-pixels SP1, SP2, SP3, and SP4 and an arrangement order of each of the sub-pixels SP1, SP2, SP3, and SP4 may be variously changed.

The non-transmissive area NTA may include a first non-transmissive area NTA1 and a second non-transmissive area NTA2.

The first non-transmissive area NTA1 may extend from the display area (see DA in FIG. 2) in a first direction (e.g., a Y-axis direction). In the display panel (see 100 in FIG. 2), a plurality of first non-transmissive areas NTA1 are disposed to be spaced apart from each other, and any one of the plurality of transmissive areas TA may be provided between two adjacent first non-transmissive areas NTA1. First signal lines (e.g., SL1 in FIG. 2) extending in a first direction (e.g., a Y-axis direction) may be disposed to be spaced apart from each other in the first non-transmissive area NTA1.

The first signal lines (see SL1 in FIG. 2) may include, for example, at least one of a common power line, a reference line, data lines, and a pixel power line.

The pixel power line may supply a first power to the driving thin film transistor of each of the sub-pixels SP1, SP2, SP3, and SP4 provided in the plurality of pixel areas P. The common power line may supply a second power to a cathode electrode of the sub-pixels SP1, SP2, SP3, and SP4 provided in the plurality of pixel areas P. In this case, the second power may be a common power supplied in common to the sub-pixels SP1, SP2, SP3, and SP4.

The reference line may supply an initialization voltage (or a reference voltage) to the driving thin film transistor of each of the sub-pixels SP1, SP2, SP3, and SP4 provided in the plurality of pixel areas P. Each of the data lines may supply a data voltage to the sub-pixels SP1, SP2, SP3, and SP4.

The second non-transmissive area NTA2 may extend from the display area (see DA in FIG. 2) in a second direction (e.g., the X-axis direction). In the display panel (see 100 in FIG. 2), a plurality of second non-transmissive areas NTA2 are disposed to be spaced apart from each other, and any one of the plurality of transmissive areas TA may be provided between two adjacent second non-transmissive areas NTA2. A second signal line SL2 may be disposed in the second non-transmissive area NTA2.

The second signal line SL2 extends in a second direction (e.g., the X-axis direction) and may include, for example, a scan line SCANL. The scan line SCANL may supply a scan signal to the sub-pixels SP1, SP2, SP3, and SP4 provided in the plurality of pixel areas P.

The first color compensation layers 241 may be formed in the plurality of transmissive areas TA. The first color compensation layers 241 may include a dye or a pigment filtering light of a predetermined color, but is not limited to this. Thus, the first color compensation layers 241 may overlap the plurality of transmissive areas TA without overlapping the emission areas of the sub-pixels SP1, SP2, SP3, and SP4. The first color compensation layers 241 may be formed to be spaced apart from each other in the second direction X, and each of the first color compensation layers 241 may extend in the first direction Y. By forming in this way, a part of the spaced apart first color compensation layer 241 may overlap the first transmissive area TA1 and the third transmissive area TA3, and another part of the spaced apart first color compensation layer 241 may overlap the second transmissive area TA2 and the fourth transmissive area TA4.

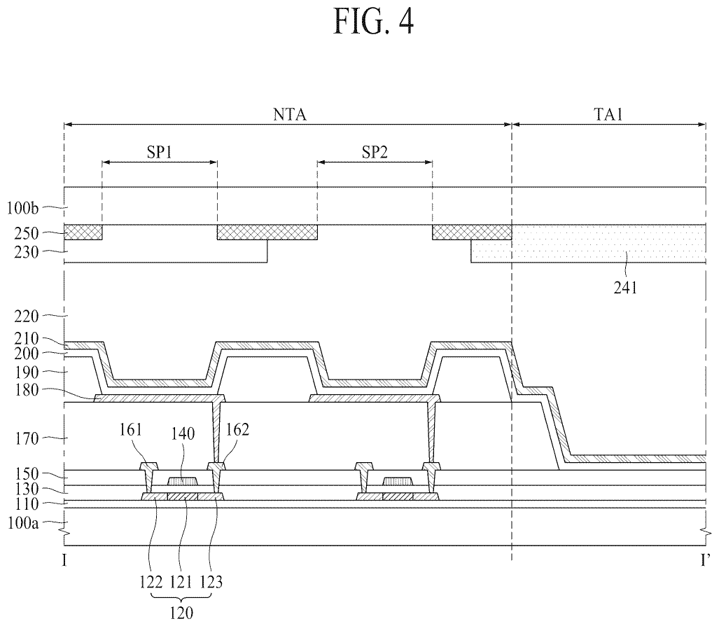

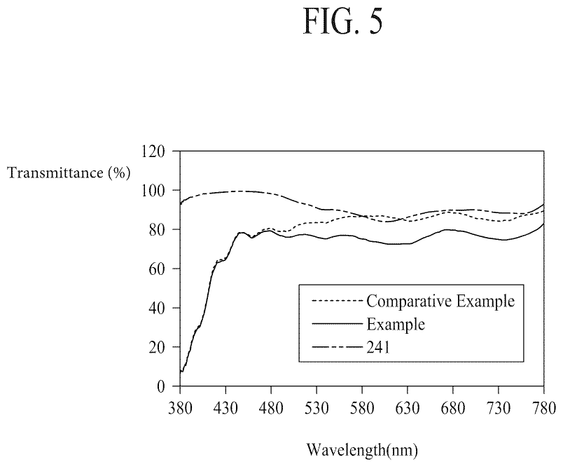

According to an embodiment of the present disclosure, a phenomenon in which the external light passing through the plurality of transmissive areas TA becomes yellowish may be prevented or reduced by the first color compensation layers 241 formed to overlap the plurality of transmissive areas TA. Meanwhile, this will be described in more detail with reference to FIGS. 4 and 5.

FIG. 4 is a cross-sectional view of a transparent display device according to an embodiment of the present disclosure. In this case, FIG. 4 corresponds to the cross-sectional view I-I′ of FIG. 1.

As shown in FIG. 4, the transparent display device according to an embodiment of the present disclosure includes a first substrate 100a, a buffer layer 110, an active layer 120, a gate insulating layer 130, a gate electrode 140, an interlayer insulating layer 150, a source electrode 161, a drain electrode 162, a planarization layer 170, a first electrode 180, a bank 190, a light emitting layer 200, a second electrode 210, an encapsulation layer 220, a color filter 230, a first color compensation layer 241, a black matrix 250, and a second substrate 100b.

The first substrate 100a may be made of glass or plastic. Particularly, the first substrate 100a may be made of transparent plastic having flexible characteristics, for example, polyimide. When the polyimide is used as the first substrate 100a, considering that a high temperature deposition process is performed on the first substrate 100a, heat resistant polyimide capable of withstanding high temperature may be used.

The buffer layer 110 may be formed on the first substrate 100a. The buffer layer 110 may protect the active layer 120 by blocking air and moisture. The buffer layer 110 may be made of an inorganic insulating material such as silicon oxide, silicon nitride, or metal oxide, but is not limited thereto and may be made of an organic insulating material.

Meanwhile, although not specifically illustrated, a light blocking layer may be formed between the first substrate 100a and the buffer layer 110. In this case, the light blocking layer may prevent light introduced from a lower side of the first substrate 100a from being directed to the active layer 120.

The active layer 120 may be formed on the buffer layer 110. The active layer 120 may include any one of a semiconductor material, for example, amorphous silicon(a-Si), polycrystalline silicon(poly-Si), and oxide semiconductor material.

The active layer 120 includes a channel part 121, a first connection part 122 provided on a first side of the channel part 121, for example, on the left side, and a second connection part 123 provided on a second side of the channel part 121, for example, on the right side.

The channel part 121 overlaps the gate electrode 140. By forming in this way, in the conductive process of conducting the active layer 120, the channel part 121 may be protected by the gate electrode 140 to maintain semiconductor characteristics without being conductive.

The first connection part 122 and the second connection part 123 may have conductive characteristics through a conductive process of performing plasma treatment on a semiconductor material or doping ions using the gate electrode 140 as a mask. The first connection part 122 and the second connection part 123 formed by the conductive process have excellent conductive characteristics and may serve as an electrode or a wiring.

The gate insulating layer 130 may be formed on the active layer 120. The gate insulating layer 130 may be formed on the entire surface of the first substrate 100a, but the present disclosure is not limited thereto, and a partial region of the gate insulating layer 130 may be patterned so that one end and another end of the gate insulating layer 130 correspond to one end and another end of the gate electrode 140, respectively.

The gate insulating layer 130 may include a silicon nitride film (SiNx) or a silicon oxide film (SiOx), but is not limited thereto. The gate insulating layer 130 may be formed of a single layer or a plurality of layers including an inorganic insulating material and/or an organic insulating material.

The gate electrode 140 may be formed on the gate insulating layer 130.

The gate electrode 140 may include at least one of an aluminum based metal such as aluminum (Al) or an aluminum alloy, a silver based metal such as silver (Ag) or a silver alloy, a copper based metal such as copper (Cu) or a copper alloy, a molybdenum based metal such as molybdenum (Mo) or a molybdenum alloy, chromium (Cr), tantalum (Ta), neodymium (Nd), and titanium (Ti). The gate electrode 140 may have a structure including one metal layer or a multilayer structure including at least two metal layers each having different physical properties.

The interlayer insulating layer 150 may be formed on the gate electrode 140. The interlayer insulating layer 150 insulates between the gate electrode 140 and the source electrode 161 and further insulates between the gate electrode 140 and the drain electrode 162. The interlayer insulating layer 150 may be formed of a single layer or a plurality of layers including an inorganic insulating material and/or an organic insulating material.

A contact hole may be formed in the interlayer insulating layer 150. Accordingly, one side of the active layer 120, for example, a part of the right side, may be exposed by one contact hole, and further, another side, for example, a part of the left side, of the active layer 120 may be exposed by the other contact hole.

The source electrode 161 and the drain electrode 162 may be disposed on the interlayer insulating layer 150.

The source electrode 161 may be electrically connected to one side of the active layer 120 (e.g., the first connection part 122) by a contact hole, and the drain electrode 162 may be electrically connected to another side of the active layer 120 (e.g., the second connection part 123) by a contact hole.

The source electrode 161 and the drain electrode 162 may be formed of the same material as the gate electrode 140, but are not limited thereto and may be formed of a material according to knowledge in the art.

The planarization layer 170 may be formed on the interlayer insulating layer 150, the source electrode 161, and the drain electrode 162. The planarization layer 170 may be formed on the source electrode 161 and the drain electrode 162 to planarize an upper surface of the planarization layer 170.

A contact hole is provided in the planarization layer 170, and a part of the upper surface of the source electrode 161 may be exposed by the contact hole. However, in some cases, a part of the upper surface of the drain electrode 162 may be exposed by the contact hole.

The planarization layer 170 may be formed of an organic insulating layer material. For example, the planarization layer 170 may be formed of an organic insulating material such as an acrylic resin, an epoxy resin, a phenolic resin, a polyamide resin, or a polyimide resin.

The first electrode 180 may be formed on the planarization layer 170 and may be electrically connected to the drain electrode 162 through a contact hole provided in the planarization layer 170. The first electrode 180 may function as an anode electrode.

The first electrode 180 may be patterned on the planarization layer 170 and patterned to correspond to each of the plurality of sub-pixels SP1 to SP4 of FIG. 3. Therefore, as shown in FIG. 4, the first electrode 180 may be patterned to correspond to the first sub-pixel SP1 and the second sub-pixel SP2.

The bank 190 may be formed on the first electrode 180. In this case, a partial region of the upper surface of the first electrode 180 exposed without being covered by the bank 190 becomes a light emitting area or an emission area.

The bank 190 may be formed of an organic layer such as an acrylic resin, an epoxy resin, a phenolic resin, a polyamide resin, a polyimide resin, or the like.

The light emitting layer 200 may be formed on the first electrode 180. The light emitting layer 200 may be formed of, for example, a white emission layer connected to all pixels. When the light emitting layer 200 is formed of a white emission layer, the light emitting layer 200 may include, for example, a first stack including a blue emission layer, a second stack including a yellow green emission layer, and a charge generation layer provided between the first stack and the second stack, but is not limited thereto.

The light emitting layer 200 may be formed over the entire surface of the first light emitting area EA1, the second light emitting area EA2, and the first transmissive area TA1. However, the present disclosure is not limited thereto, and the light emitting layer 200 may be partially patterned and may not be provided in the first transmissive area TA1.

According to an embodiment of the present disclosure, the light emitting layer 200 provided in the first sub-pixel SP1 and the second sub-pixel SP2 may emit, for example, light of white color.

The second electrode 210 may be formed on the light emitting layer 200. The second electrode 210 may function as a cathode.

The second electrode 210 may be formed on, for example, the bank 190 and the light emitting layer 200. Accordingly, the second electrode 210 may be formed over the entire surfaces of the first light emitting area EA1, the second light emitting area EA2, and the first transmissive area TA1. However, the present disclosure is not limited thereto, and the second electrode 210 may be partially patterned and may not be provided in the first transmissive area TA1.

The encapsulation layer 220 may be formed on the second electrode 210. The encapsulation layer 220 may be formed on the entire surface of the first substrate 100a. Thus, it may be formed on the entire surfaces of the first sub pixel SP1, the second sub pixel SP2, and the first transmissive area TA1.

The encapsulation layer 220 may include acrylic resin, epoxy resin, polyimide, polyethylene (PE), or silicon oxycarbon (SiOC).

However, although not specifically illustrated, the encapsulation layer 220 may include a first encapsulation layer including an inorganic material, a second encapsulation layer including an organic material, and a third encapsulation layer including an inorganic material.

The color filter 230 may be formed on the encapsulation layer 220. Specifically, the color filter 230 may be formed to correspond to the first sub-pixel SP1.

The color filter 230 may transmit light of any one of red, green, and blue colors. Accordingly, light emitted from the light emitting layer 200 provided in the first sub-pixel SP1 passes through the color filter 230 to be emitted to the outside. In this case, when the light emitted from the light emitting layer 200 is white and the color filter 230 is a red color filter that transmits red light, red light may be emitted from the first sub-pixel SP1. However, the present disclosure is not limited thereto, and light of various colors may be emitted from the first sub-pixel SP1 according to a combination of the light emitting layer 200 and the color filter 230 provided in the first sub-pixel SP1.

According to an embodiment of the present disclosure, a separate color filter may not be formed in the second sub-pixel SP2. Furthermore, as light of white color is emitted from the light emitting layer 200 provided in the second sub-pixel SP2, light of white color may be emitted from the second sub-pixel SP2.

Meanwhile, since a separate color filter is not formed in the second sub-pixel SP2, the encapsulation layer 220 provided in the second sub-pixel SP2 may contact a portion of the lower surface of the second substrate 100b. For example, the encapsulation layer 220 is in direct contact with a portion of the lower surface of the second substrate 100b.

According to an embodiment of the present disclosure, the first color compensation layer 241 may be formed in the first transmissive area TA1. Specifically, the first color compensation layer 241 may be formed on the encapsulation layer 220 provided in the first transmissive area TA1. In this case, the first color compensation layer 241 may be formed on the same layer as the color filter 230. Thus, the first color compensation layer 241 is on a same plane as the color filter 230. In one embodiment, a thickness of the color filter 230 is a same as a thickness of the first color compensation layer 241 as shown in FIG. 4. However, the thickness of the color filter 230 may be different from the thickness of the first color compensation layer 241.

Conventionally, there was a problem in that external light reflected from an object or background located on the back surface of the first substrate 100a by a plurality of insulating layers provided in the first transmissive area TA1, for example, a buffer layer, a gate insulating layer, and an interlayer insulating layer, and flowing through the first transmissive area TA1 was perceived yellow by an observer.

According to an embodiment of the present disclosure, when the first color compensation layer 241 is formed in the first transmissive area TA1, light that flows through the first transmissive area TA1 and becomes yellowish while passing through the plurality of insulating layers is emitted to the outside through the first color compensation layer 241 without the yellowish color, a problem in which light is perceived yellow may be prevented or reduced. Thus, the first color compensation layer 241 filters external light of a predetermined color (e.g., yellow) that passes through the first transmissive area TA1.

On the other hand, the principle of preventing or removing the problem of yellowing the light passing through the first color compensation layer 241 of the first transmissive area TA1 provided in the transparent display device according to an embodiment of the present disclosure will be described in more detail with reference to FIG. 5.

The black matrix 250 may be formed on the encapsulation layer 220, the color filter 230, and the first color compensation layer 241. In detail, the black matrix 250 may be formed between the first sub-pixel SP1 and the second sub-pixel SP2, and in this case, the black matrix 250 may be formed on the encapsulation layer 220 and the color filter 230. For example, a portion of the color filter 230 is between the encapsulation layer 220 and the black matrix 250. Also, the black matrix 250 may be formed between the second sub-pixel SP2 and the first transmissive area TA1, and in this case, the black matrix 250 may be formed on the encapsulation layer 220 and the first color compensation layer 241. Thus, a portion of the first color compensation layer 241 is between the encapsulation layer 220 and the black matrix 250.

The black matrix 250 overlaps the bank 190 and is formed between the first sub-pixel SP1 and the second sub-pixel SP2, thereby preventing a problem that light emitted from the first sub-pixel SP1 and the second sub-pixel SP2 is mixed with each other and mixed with each other. That is, the black matrix 250 is non-overlapping with the light emitting area of each sub-pixel.

The second substrate 100b may be formed on the black matrix BM. The second substrate 100b may be bonded to face the first substrate 100a.

The second substrate 100b may be made of glass or plastic. In particular, the second substrate 100b may be made of transparent plastic having flexible characteristics, for example, polyimide.

FIG. 5 is a graph illustrating a transmittance according to a wavelength of a color compensation layer of a transparent display device according to an embodiment of the present disclosure.

As can be seen from FIG. 5, the graph of the dotted line relates to the transparent display device according to the comparative example in which the color compensation layer is not provided in the first transmission area and shows the transmittance of the light emitted through the first transmission area by wavelength, and the graph of the solid line relates to the transparent display device according to an embodiment of the present invention in which the first color compensation layer (see TA1 of FIG. 4) is provided in the first transmission area (see TA1 of FIG. 4), and the graph of the two-dot chain line is a graph showing the transmittance of the first color compensation layer (see TA1 of FIG. 4) provided in the first transmission area (see TA1 of FIG. 4) by wavelength. In this case, the transmittance refers to the relative transmittance of the light when the maximum transmittance of light is 100% in the wavelength range from 380 nm to 780 nm of the first color compensation layer (241 of FIG. 4).

First, as may be seen from the graph of the two-dot chain line, the first color compensation layer 241 according to an embodiment of the present disclosure has a transmittance of light in a wavelength range greater than or equal to 380 nm and less than 550 nm and is higher than that of light in a wavelength range from 550 nm to 780 nm, and a transmittance of light is 80% or more in a wavelength range from 380 nm to 780 nm. That is, the first color compensation layer 241 has a transmittance of light in a first wavelength range not less than 380 nm and less than 500 nm that is greater than a transmittance of light in a second wavelength range from 500 nm to 780 nm. Accordingly, it may be seen that the first color compensation layer 241 according to an embodiment of the present disclosure has a relatively higher transmittance of blue (B) light than that of green (G) light and red (R) light.

According to an embodiment of the present disclosure, the first color compensation layer 241 may prevent yellow light from being visually recognized while passing through a plurality of insulating layers provided in the first transmission area TA1 of FIG. 4. Therefore, the first transmission area TA1 may be neatly maintained as a transparent area.

As a result, it can be seen from the graph of the dotted line that the transmittance of light in the wavelength range of 480 nm or more and less than 780 nm was seen to be yellowish, while it can be seen from the graph of the solid line that the transmittance of light in the wavelength range of 480 nm or more and less than 780 nm is reduced to 80% or less. Taken together, it can be confirmed that by forming the first color compensation layer 241, the phenomenon in which the light passing through the first transmissive area TA1 looks yellowish is reduced.

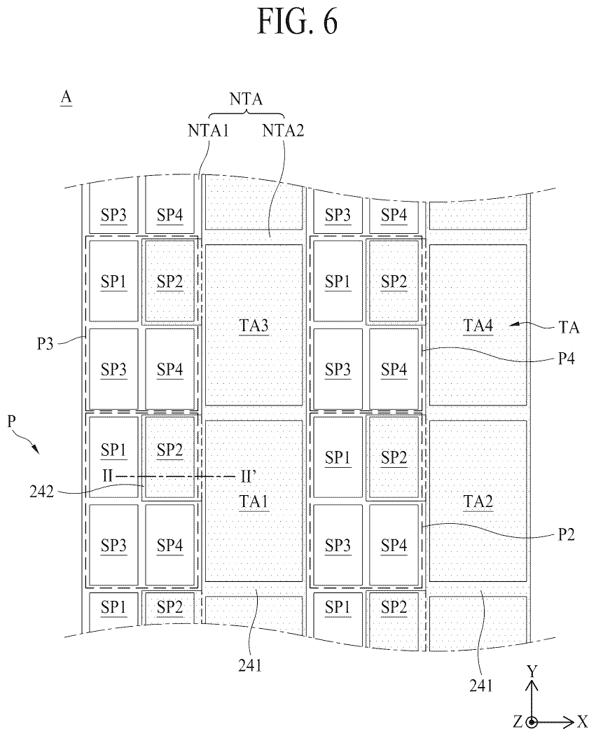

FIG. 6 is a plan view of a transparent display device according to another embodiment of the present disclosure. In this case, FIG. 6 is an enlarged view of an area A of FIG. 2. Meanwhile, an embodiment of FIG. 6 is the same as an embodiment of FIG. 3 except for the configuration of the second color compensation layer, and thus different configurations will be mainly described below.

As shown in FIG. 6, a transparent display device according to another embodiment of the present disclosure includes a plurality of pixel areas P, a plurality of transmissive areas TA, a plurality of non-transmissive areas NTA, and color compensation layers 241 and 242.

According to another embodiment of the present disclosure, color compensation layers 241 and 242 may be formed in the plurality of transmissive areas TA and formed in any one sub-pixel SP2 of the sub-pixels SP1 to SP4 provided in the plurality of pixel areas P. Specifically, the color compensation layers 241 and 242 may include a first color compensation layer 241 and a second color compensation layer 242. In this case, since the first color compensation layer 241 is the same as the first color compensation layer described above with reference to FIG. 3, repeated descriptions thereof will be omitted.

The second color compensation layer 242 may be formed in the second sub-pixel SP2 provided in any one of the plurality of pixel areas P. In this case, the second sub-pixel SP2 may emit light of white color, for example.

The second color compensation layer 242 may be formed on one side of the first color compensation layer 241, for example, on the left side thereof. In this case, the second color compensation layer 242 may be formed of the same material as the first color compensation layer 241, and may be continuously formed with the first color compensation layer 241.

The second color compensation layer 242 may be formed in the second sub-pixel SP2 in the first pixel area P1. Likewise, it may be formed in the second sub-pixel SP2 in the second pixel area P2, the second sub-pixel SP2 in the third pixel area P3, and the second sub-pixel SP2 in the fourth pixel area P4. In this case, the second sub-pixel SP2 may emit light of white color, for example.

According to another embodiment of the present disclosure, since the second color compensation layer 242 is formed in the second sub-pixel SP2 provided in the first pixel area P1 to the fourth pixel area P4 and emitting light of white color, the color temperature of the white may be increased, and the luminance of the second sub-pixel SP2 emitting light of white color may be increased, and as the second color compensation layer 242 is formed, the reflectance of external light in the second sub-pixel SP2 may be reduced and visibility may be improved. In one embodiment, the second color compensation layer 242 filters light of the predetermined color (e.g., yellow light) similar to the first color compensation layer 241. By filtering the light of the predetermined color, the luminance of the second sub-pixel SP2 emitting light of white color may be increased.

Furthermore, according to another embodiment of the present disclosure, the second color compensation layer 242 may absorb and block light having a wavelength equal to or less than 380 nm. Accordingly, by blocking the ultraviolet rays from entering the second sub-pixel SP2 emitting the light of white color, the second color compensation layer 242 may prevent an element provided under the second sub-pixel SP2 from being damaged by the ultraviolet rays.

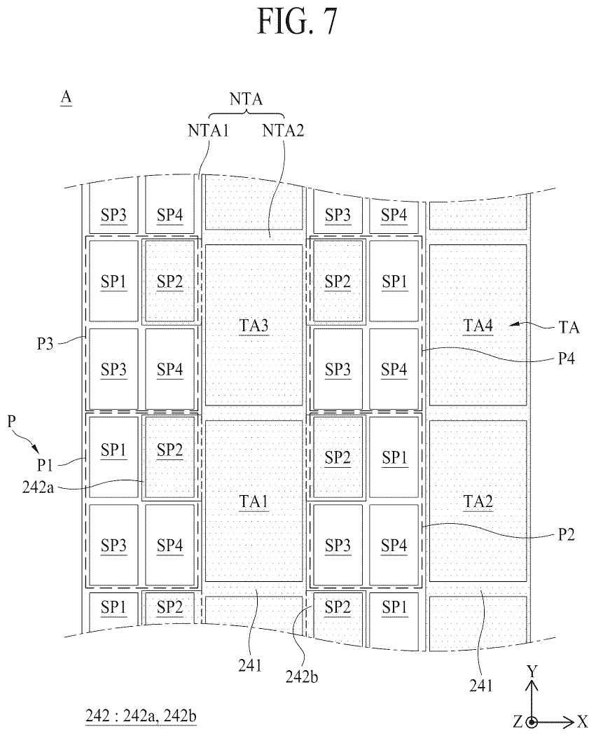

FIG. 7 is a plan view of a transparent display device according to another embodiment of the present disclosure. In this case, FIG. 7 is an enlarged view of an area A of FIG. 2. Meanwhile, an embodiment of FIG. 7 is the same as an embodiment of FIG. 6 except for the arrangement of the second color compensation layer, and thus different configurations will be mainly described below.

The transparent display device according to another embodiment of the present disclosure includes a plurality of pixel areas P, a plurality of transmissive areas TA, a plurality of non-transmissive areas NTA, and color compensation layers 241, 242a and 242b.

According to another embodiment of the present disclosure, unlike FIG. 6, the pixel arrangement of the first sub-pixel SP1 to the fourth sub-pixel SP4 provided in the second pixel area P2 and the fourth pixel area P4 is partially different from that of the first pixel area P1 and the third pixel area P3. Specifically, the arrangement of the first sub-pixel SP1 and the second sub-pixel SP2 provided in the second pixel area P2 and the fourth pixel area P4 is opposite to that of the first pixel area P1 and the third pixel area P3.

Therefore, the first sub-pixel SP1 and the second sub-pixel SP2 provided in the first pixel area P1 are symmetrically provided with the first sub-pixel SP1 and the second sub-pixel SP2 provided in the second pixel area P2 with respect to the first transmissive area TA1, and similarly, the first sub-pixel SP1 and the second sub-pixel SP2 provided in the third pixel area P3 are symmetrically provided with the first sub-pixel SP1 and the second sub-pixel SP2 provided in the fourth pixel area P4 with respect to the third transmissive area TA3.

Color compensation layers 241, 242a, and 242b may be formed in the plurality of transmissive areas TA and may be formed in the second sub-pixel SP2 among the sub-pixels SP1 to SP4 provided in the plurality of pixel areas P. Specifically, the color compensation layers 241, 242a, and 242b may include a first color compensation layer 241 and second color compensation layers 242a and 242b. In this case, since the first color compensation layer 241 is the same as the first color compensation layer described above with reference to FIG. 3, repeated descriptions thereof will be omitted.

The second color compensation layers 242a and 242b include a second color compensation layer 242a provided on a first side of the first color compensation layer 241, for example, on the left side, and a second color compensation layer 242b provided on a second side of the first color compensation layer 241, for example, on the right side. In this case, the second color compensation layer 242a provided on the first side of the first color compensation layer 241 is formed in the second sub-pixel SP2 provided in the first pixel area P1 and the third pixel area P3, and the second color compensation layer 242b provided on the second side of the first color compensation layer 241 may be formed in the second sub-pixel SP2 provided in the second pixel area P2 and the fourth pixel area P4.

According to another embodiment of the present disclosure, the second color compensation layers 242a and 242b may not be provided on the first side and the second side of the first color compensation layer 241 formed in the second transmissive area TA2 and the fourth transmissive area TA4. Although not shown in detail in the drawings, the first to fourth pixel areas P1 to P4 and the first to fourth transmissive areas TA1 to TA4 shown in FIG. 7 may be formed in a structure that is alternately repeated in the second direction X. Thus, the first transmissive area TA1, the third transmissive area TA3, the first color compensation layer 241, and the second color compensation layers 242a and 242b may be provided on the right sides of the second transmissive area TA2, the fourth transmissive area TA4, and the first color compensation layer 241.

According to another embodiment of the present disclosure, since the second color compensation layers 242a and 242b are formed in the second sub-pixel SP2 provided in the first pixel area P1 to the fourth pixel P4 and emitting light of white color, the color temperature of white may be increased, and the luminance of the second sub-pixel SP2 emitting light of white color may be increased, and the reflectance of external light in the second sub-pixel SP2 may be reduced and visibility may be improved.

Furthermore, according to another embodiment of the present disclosure, the second color compensation layer 242 may absorb and block light having a wavelength equal to or less than 380 nm. Accordingly, by blocking the ultraviolet rays from entering the second sub-pixel SP2 emitting the light of white color, the second color compensation layer 242 may prevent a device provided under the second sub-pixel SP2 from being damaged by the ultraviolet rays.

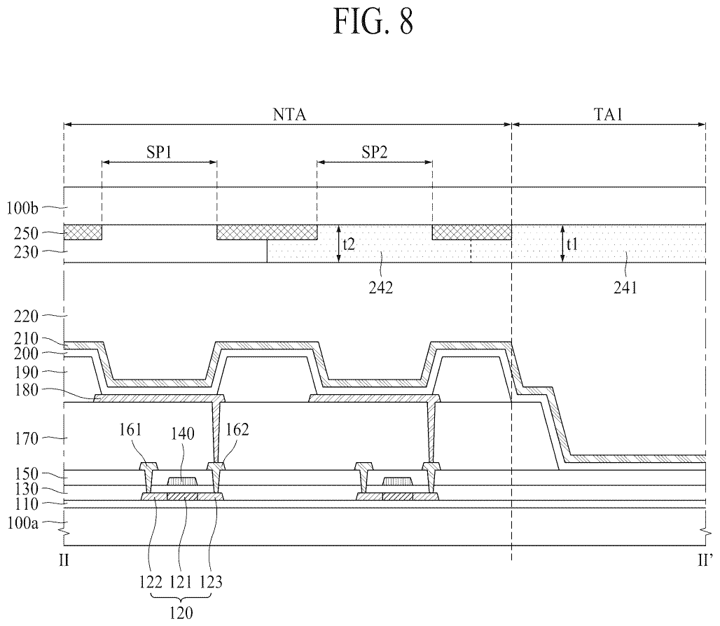

FIG. 8 is a cross-sectional view of a transparent display device according to another embodiment of the present disclosure. In this case, FIG. 8 corresponds to the cross-section II-II′ of FIG. 6. Meanwhile, an embodiment of FIG. 8 is the same as an embodiment of FIG. 4 except for the configuration of the second color compensation layer, and thus different configurations will be mainly described below.

As shown in FIG. 8, the transparent display device according to another embodiment of the present disclosure includes a first substrate 100a, a buffer layer 110, an active layer 120, a gate insulating layer 130, a gate electrode 140, an interlayer insulating layer 150, a source electrode 161, a drain electrode 162, a planarization layer 170, a first electrode 180, a bank 190, a light emitting layer 200, a second electrode 210, an encapsulation layer 220, a color filter 230, a first color compensation layer 241, a second color compensation layer 242, a black matrix 250, and a second substrate 100b.

According to another embodiment of the present disclosure, the second color compensation layer 242 may be formed in the second sub-pixel SP2. Specifically, the second color compensation layer 242 may be formed on the encapsulation layer 220 provided in the second sub-pixel SP2. In this case, the second color compensation layer 242 may be formed on the same layer as the color filter 230 and the first color compensation layer 241.

The second color compensation layer 242 may be formed of the same material in the same process as the process of forming the first color compensation layer 241. The second color compensation layer 242 may be provided continuously with the first color compensation layer 241.

Since the second color compensation layer 242 includes the same material as the first color compensation layer 241, as described above in FIG. 5, the second color compensation layer 242 may be provided such that the transmittance of light in the wavelength range of not less than 380 nm and less than 550 nm is higher than the transmittance of light in the wavelength range of 550 nm to 780 nm, and the transmittance of light in the wavelength range of 380 nm to 780 nm is 80% or more.

The second color compensation layer 242 is formed in the same process as the process of forming the first color compensation layer 241, and the first thickness t1 of the first color compensation layer 241 and the second thickness t2 of the second color compensation layer 242 may be the same. In this case, the first thickness t1 and the second thickness t2 may be defined as the shortest distance from the lower surface to the upper surface of each of the first color compensation layer 241 and the second color compensation layer 242.

According to another embodiment of the present disclosure, since the second color compensation layer 242 is formed in the second sub-pixel SP2 provided in the first pixel area P1 to the fourth pixel area P4 and emitting light of white color, the white color temperature may be increased, and the luminance of the second sub-pixel SP2 emitting light of white color may be increased, and as the second color compensation layer 242 is formed, the reflectance of external light in the second sub-pixel SP2 may be reduced and visibility may be improved.

Furthermore, according to another embodiment of the present disclosure, the second color compensation layer 242 may absorb and block light having a wavelength equal to or less than 380 nm. Accordingly, by blocking the ultraviolet rays from entering the second sub-pixel SP2 emitting the light of white color, the second color compensation layer 242 may prevent a device provided under the second sub-pixel SP2 from being damaged by the ultraviolet rays.

In addition, according to an embodiment of the present disclosure, the second color compensation layer 242 is formed in the second sub-pixel SP2 that emits white, and the second color compensation layer 242 is not formed in the first sub-pixel SP1, the third sub-pixel SP3, and the fourth sub-pixel SP4 that emit light of red, green, and blue, so that the luminance of each of the first sub-pixel SP1, the third sub-pixel SP3, and the fourth sub-pixel SP4 in the first to fourth pixel areas P1 to P4 may be improved without being lowered by the second color compensation layer 242. Furthermore, since the second color compensation layer 242 is formed in the second sub-pixel SP2 among the sub-pixels SP1 to SP4, a color shift phenomenon, which is a phenomenon in which color is expressed differently from the color desired to be implemented in each of the sub-pixels SP1, SP3, and SP4 that emit light of red, green, and blue, is reduced or prevented, enabling accurate and clear color implementation.

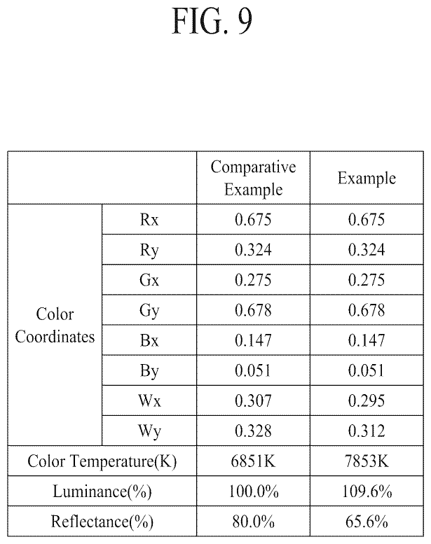

FIG. 9 is a table comparing a transparent display device according to another embodiment of the present disclosure with a transparent display device according to a comparative example. In this case, the transparent display device according to Comparative Example relates to a transparent display device that does not include a first color compensation layer and a second color compensation layer, and the transparent display device according to example relates to a transparent display device according to an embodiment of FIG. 8. Specifically, a FIG. 9 relates to a second sub-pixel (see SP2 of FIG. 8) emitting light of white color, and a comparative example in FIG. 9 relates to a sub-pixel that emits light of white color and does not have a separate color compensation layer.

As shown in FIG. 9, according to an embodiment of the present disclosure, it may be confirmed that the color temperature is increased from 6851 K to 7853 K, as compared to the comparative example. Since the color temperature is increased, the luminance of the second sub-pixel (see SP2 of FIG. 8) emitting light of white color may be increased. Accordingly, in the case of an embodiment of the present disclosure, the luminance in the second sub-pixel (see SP2 of FIG. 8) is 109.6%, which is an increase of about 9.6% as compared to the comparative example. In this case, the luminance in the second sub-pixel (see SP2 of FIG. 8) of an embodiment may be defined as a relative luminance when the luminance in the comparative example is assumed to be 100%.

Meanwhile, according to another embodiment of the present disclosure, even when the color compensation layer is formed in the second sub-pixel (see SP2 in FIG. 8), it may be seen that the color coordinates Wx and Wy in the second sub-pixel SP2 emitting light of white color are slightly changed from (0.307, 0.328) to (0.295, 0.312). Meanwhile, in the color coordinates of FIG. 9, (Rx, Ry), (Gx, Gy), (Bx, By), and (Wx, Wy) mean the color coordinates (x, y) in the sub-pixel emitting red, green, blue, and light of white color, respectively.

According to another embodiment of the present disclosure, when the second sub-pixel (see SP2 in FIG. 8) emits light, light of white color with improved luminance according to an increase in color temperature may be implemented without significantly changing the color coordinate.

Furthermore, when the second color compensation layer 242 is formed on the second sub-pixel (see SP2 of FIG. 8) emitting light of white color, it may be confirmed that the reflectance of the embodiment of the present disclosure is 65.6%, and the reflectance is reduced by 14.4% compared to the comparative example. Accordingly, in the case of the transparent display device according to the embodiment of the present disclosure, a problem in which external light is reflected from a sub-pixel emitting light of white color to deteriorate visibility may be prevented or removed. In this case, the reflectance may be defined as a relative ratio of light that is reflected from the inside of the transparent display device and is emitted to the outside, assuming that light flowing into the inside of the transparent display device is 100%.

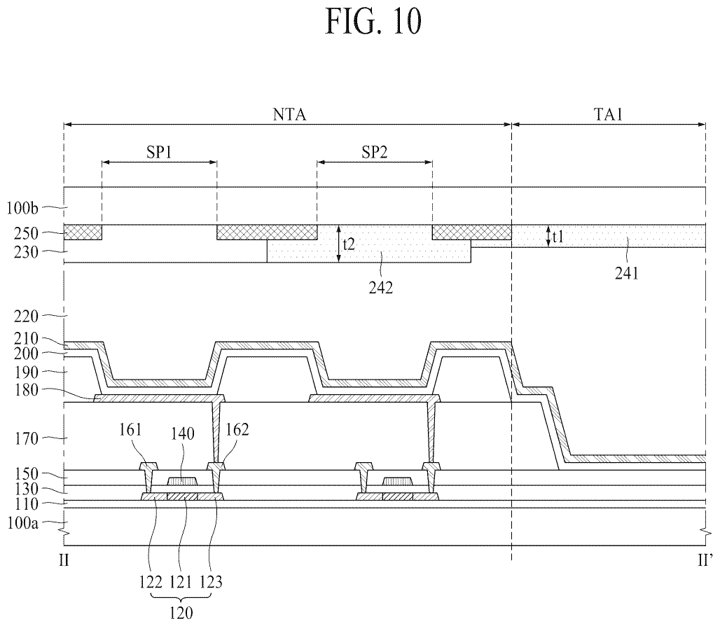

FIG. 10 is a cross-sectional view of a transparent display device according to another embodiment of the present disclosure. In this case, FIG. 10 corresponds to the cross-section II-II′ of FIG. 6. Meanwhile, an embodiment of FIG. 10 is the same as an embodiment of FIG. 8 except for the configurations of the first color compensation layer and the second color compensation layer, and thus different configurations will be mainly described below.

As shown in FIG. 10, a transparent display device according to another embodiment of the present disclosure includes a first substrate 100a, a buffer layer 110, an active layer 120, a gate insulating layer 130, a gate electrode 140, an interlayer insulating layer 150, a source electrode 161, a drain electrode 162, a planarization layer 170, a first electrode 180, a bank 190, a light emitting layer 200, a second electrode 210, an encapsulation layer 220, a color filter 230, a first color compensation layer 241, a second color compensation layer 242, a black matrix 250, and a second substrate 100b.

According to another embodiment of the present disclosure, the first color compensation layer 241 and the second color compensation layer 242 may have different thicknesses. Specifically, the first thickness t1 of the first color compensation layer 241 may be less than the second thickness t2 of the second color compensation layer 242.

Since the first thickness t1 of the first color compensation layer 241 is different from the second thickness t2 of the second color compensation layer 242, the first color compensation layer 241 and the second color compensation layer 242 are continuously provided, a boundary portion between the first color compensation layer 241 and the second color compensation layer 242 may be stepped. In this case, the stepped portion between the first color compensation layer 241 and the second color compensation layer 242 may overlap the black matrix 250 provided between the first color compensation layer 241 and the second color compensation layer 242.

By forming in this way, even if the second thickness t2 is increased to reduce the reflectance in the second sub-pixel SP2 emitting light of white color, the first thickness t1 in the first transmissive area TA1 is smaller than the second thickness t2, and thus the transmittance in the first transmissive area TA1 may be maintained below a certain level. Accordingly, an object or a background located on the rear surface of the first substrate 100a may be clearly visible by the light passing through the first transmissive area TA1.

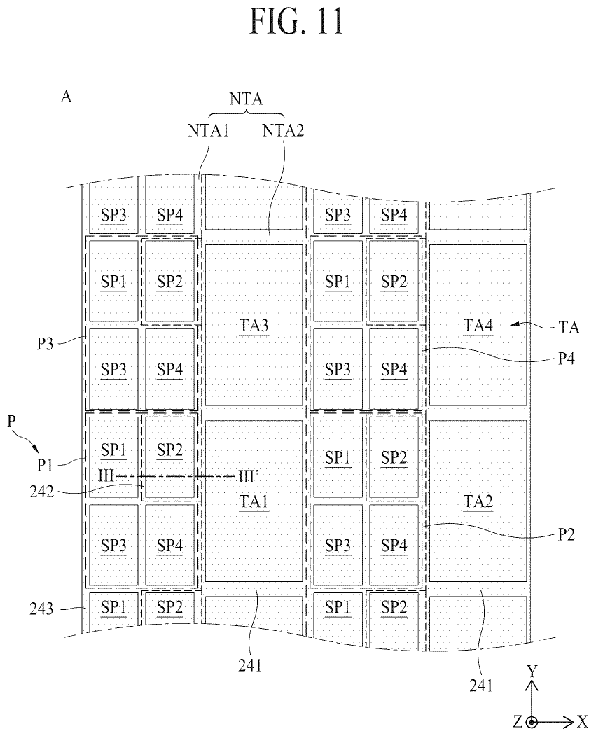

FIG. 11 is a plan view of a transparent display device according to another embodiment of the present disclosure. In this case, FIG. 11 is an enlarged view of an area A of FIG. 2. Meanwhile, an embodiment of FIG. 11 is the same as an embodiment of FIG. 6 except for the third color compensation layer, and thus different configurations will be mainly described below.

As shown in FIG. 11, a transparent display device according to another embodiment of the present disclosure includes a plurality of pixel areas P, a plurality of transmissive areas TA, a plurality of non-transmissive areas NTA, and color compensation layers 241, 242, and 243.

According to another embodiment of the present disclosure, the color compensation layers 241, 242, and 243 may be formed on entire surfaces of the plurality of transmissive areas TA and the plurality of pixel areas P. In this case, the color compensation layers 241, 242, and 243 include a first color compensation layer 241, a second color compensation layer 242, and a third color compensation layer 243. Specifically, a first color compensation layer 241 is formed in the plurality of transmissive areas TA, and the second color compensation layer 242 is formed in the second sub-pixel SP2 among the sub-pixels SP1 to SP4 provided in the plurality of pixel areas P, and a third color compensation layer 243 may be formed in the first sub-pixel SP1, the third sub-pixel SP3, and the fourth sub-pixel SP4 provided in the plurality of pixel areas P. In this case, the first color compensation layer 241 and the second color compensation layer 242 are the same as those of the first and second color compensation layers described above with reference to FIG. 6, and repeated descriptions thereof will be omitted.

According to another embodiment of the present disclosure, the color compensation layers 241, 242, and 243 may be formed on the entire surfaces of the plurality of transmissive areas TA and the plurality of pixel areas P. By forming in this way, it is not necessary to separately form the pattern of the color compensation layers 241, 242, and 243 to form the first color compensation layer 241 and the second color compensation layer 242, and thus the process cost may be reduced by simplifying the manufacturing process and not adding the manufacturing process.

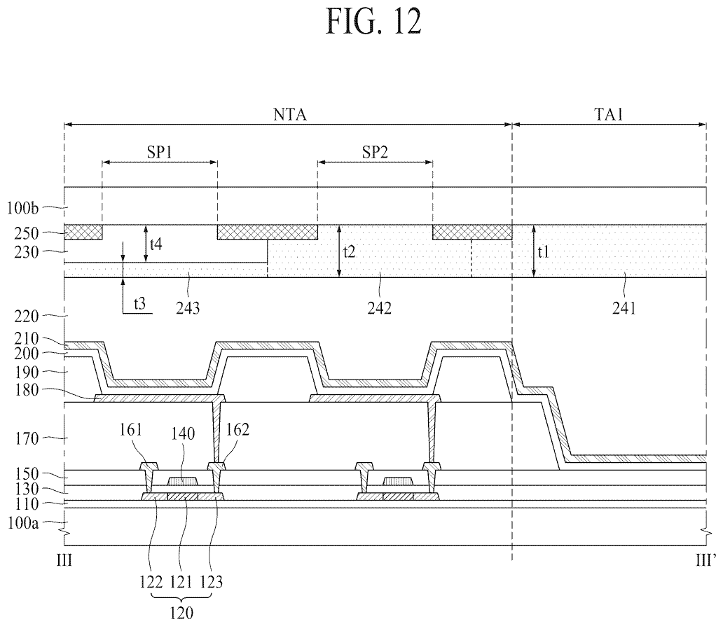

The third color compensation layer 243 may be formed in an area where the first color compensation layer 241 and the second color compensation layer 242 are not formed among the plurality of transmissive areas TA and areas where the plurality of pixel areas P are formed. As shown in FIG. 12, the third color compensation layer 243 is on the color filter 230 such that the third color compensation layer 243 is between the first color filter 230 and the first substrate 100a.

The third color compensation layer 243 may be formed in the first sub-pixel SP1, the third sub-pixel SP3, and the fourth sub-pixel SP4 provided in any one of the plurality of pixel areas P, for example. In this case, the first sub-pixel SP1, the third sub-pixel SP3, and the fourth sub-pixel SP4 may emit red, green, and blue light, respectively, but are not limited thereto.

FIG. 12 is a cross-sectional view of a transparent display device according to another embodiment of the present disclosure. In this case, FIG. 12 corresponds to the cross-section III-III′ of FIG. 11. Meanwhile, an embodiment of FIG. 12 is the same as an embodiment of FIG. 8 except for the configuration of the third color compensation layer, and thus different configurations will be mainly described below.

As shown in FIG. 12, a transparent display device according to another embodiment of the present disclosure includes a first substrate 100a, a buffer layer 110, an active layer 120, a gate insulating layer 130, a gate electrode 140, an interlayer insulating layer 150, a source electrode 161, a drain electrode 162, a planarization layer 170, a first electrode 180, a bank 190, a light emitting layer 200, a second electrode 210, an encapsulation layer 220, a color filter 230, a first color compensation layer 241, a second color compensation layer 242, a third color compensation layer 243, a black matrix 250, and a second substrate 100b.

According to another embodiment of the present disclosure, the third color compensation layer 243 may be formed in the first sub-pixel SP1. Specifically, the third color compensation layer 243 may be formed between the encapsulation layer 220 and the color filter 230 provided in the first sub-pixel SP1.

The third color compensation layer 243 may be formed of the same material in the same process as the process of forming the first color compensation layer 241 and the second color compensation layer 242. Accordingly, the third color compensation layer 243 may be provided continuously with the first color compensation layer 241 and/or the second color compensation layer 242.

Since the third color compensation layer 243 includes the same material as the first color compensation layer 241 and the second color compensation layer 242, as described above in FIG. 5, the third color compensation layer 243 may have a light transmittance in a wavelength range greater than or equal to 380 nm and less than 550 nm is greater than a light transmittance in a wavelength range from 550 nm to 780 nm, and a light transmittance in a wavelength range greater than or equal to 380 nm and less than or equal to 780 nm is greater than or equal to 80%. Thus, the third color compensation layer 243 filters light of the predetermined color (e.g., yellow light) similar to the first color compensation layer 241 and the second color compensation layer 242. By filtering the light of the predetermined color, the luminance of the third sub-pixel SP1 may be increased.

The third color compensation layer 243 may have a third thickness t3. In this case, the third thickness t3 may be defined as the shortest distance from the upper surface to the lower surface of the third color compensation layer 243. According to another embodiment of the present disclosure, the third thickness t3 of the third color compensation layer 243 may be formed to have a thickness less than the first thickness t1 of the first color compensation layer 241 and the second thickness t2 of the second color compensation layer 242.

Meanwhile, the color filter 230 may have a fourth thickness t4, and in this case, the fourth thickness t4 may be defined as the shortest distance from the upper surface to the lower surface of the color filter 230. The sum of the fourth thickness t4 of the color filter 230 and the third thickness t3 of the third color compensation layer 243 may be the same as the first thickness t1 of the first color compensation layer 241 or the second thickness t2 of the second color compensation layer 242.

According to another embodiment of the present disclosure, by forming the first color compensation layer 241, the second color compensation layer 242, and the third color compensation layer 243 on the front surface of the first transmissive area TA1, the first sub-pixel SP1, and the second sub-pixel SP2, it is not necessary to add a separate patterning process, thereby simplifying the manufacturing process and reducing the manufacturing cost.

Accordingly, the present disclosure may have the following advantages.

According to an embodiment of the present disclosure, by forming a color compensation layer having a high transmittance in a specific wavelength range in the transmissive area, a phenomenon in which light passing through the transmissive area becomes yellowish may be prevented or removed.

According to an embodiment of the present disclosure, by forming a color compensation layer having a high transmittance in a specific wavelength range in a sub-pixel emitting light of white color, the color temperature of light of white color may be increased, and thus the luminance of the sub-pixel emitting light of white color may be improved.

According to an embodiment of the present disclosure, by forming a color compensation layer with a high transmittance in a specific wavelength range in the sub-pixel emitting light of white color, the reflectance of the sub-pixel emitting light of white color can be reduced, and accordingly, the problem of reducing visibility by reflecting external light from the sub-pixel emitting light of white color can be solved.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A transparent display device comprising:
a first substrate including a display area that display an image and a transmissive area that is more transmissive of light than the display area;
a first sub-pixel and a second sub-pixel in the display area;
a first color filter in the display area, the first color filter overlapping the first sub-pixel; and
a first color compensation layer in the transmissive area, the first color compensation layer filters light of a predetermined color that passes through the transmissive area.

2. The transparent display device according to claim 1, wherein the first color compensation layer has a transmittance of light in a first wavelength range not less than 380 nm and less than 500 nm that is greater than a transmittance of light in a second wavelength range from 500 nm to 780 nm,
wherein the transmittance of light in the first and the second wavelength range is greater than or equal to 80%.

3. The transparent display device according to claim 1, wherein the first color compensation layer is on a same layer as the first color filter.

4. The transparent display device according to claim 1, wherein the first sub-pixel emits any one of red light, green light, and blue light, and the second sub-pixel emits white light.

5. The transparent display device according to claim 1, further comprising:
an encapsulation layer on the first sub-pixel and the second sub-pixel; and
a second substrate on the encapsulation layer such that the encapsulation layer is between the second substrate and the first substrate,
wherein a portion of the encapsulation layer in the second sub-pixel is in direct contact with the second substrate.

6. The transparent display device according to claim 1, further comprising:
a second color compensation layer in the second sub-pixel, the second color compensation layer filtering light of the predetermined color,
wherein the second sub-pixel emits white light and the first sub-pixel emits any one of red light, green light, and blue light.

7. The transparent display device according to claim 6, wherein the second color compensation layer includes a same material as the first color compensation layer and a thickness of the second color compensation layer is a same as a thickness of the first color compensation layer.

8. The transparent display device according to claim 6, wherein the first color compensation layer and the second color compensation layer are continuously disposed.

9. The transparent display device according to claim 6, further comprising:
a third color compensation layer on the first color filter such that the third color compensation layer is between the first color filter and the first substrate, the third color compensation layer filtering light of the predetermined color.

10. The transparent display device according to claim 9, wherein a thickness of the third color compensation layer is less than a thickness of the first color compensation layer or a thickness of the second color compensation layer.

11. The transparent display device according to claim 9, wherein the third color compensation layer includes a same material as the first color compensation layer or the second color compensation layer.

12. The transparent display device according to claim 9, wherein a sum of a thickness of the first color filter and a thickness of the third color compensation layer is a same as a thickness of the first color compensation layer or a thickness of the second color compensation layer.

13. The transparent display device according to claim 6, wherein the second color compensation layer includes a same material as the first color compensation layer and a thickness of the second color compensation layer is greater than a thickness of the first color compensation layer.

14. The transparent display device according to claim 6, further comprising:
a black matrix between the second sub-pixel and the transmissive area,
a stepped portion between the first color compensation layer and the second color compensation layer, the stepped portion overlapping the black matrix.

15. A transparent display device comprising:
a first pixel area including a first sub-pixel to a fourth sub-pixel of the first pixel area;
a second pixel area including a first sub-pixel to a fourth sub-pixel of the second pixel area;
a first transmissive area between the first pixel area and the second pixel area; and
a first color compensation layer in the first transmissive area,
wherein the first color compensation layer has a transmittance of light in in a first wavelength range not less than 380 nm and less than 500 nm that is greater than a transmittance of light in a second wavelength range from 500 nm to 780 nm, and the transmittance of light in the first and the second wavelength range at least 80%.

16. The transparent display device according to claim 15, further comprising:
a third pixel area including a first sub-pixel to a fourth sub-pixel of the third pixel area;
a fourth pixel area including a first sub-pixel to a fourth sub-pixel of the fourth pixel area; and
a second transmissive area between the third pixel area and the fourth pixel area wherein the first color compensation layer is disposed continuously in the first transmissive area and the second transmissive area.

17. The transparent display device according to claim 15, further comprising:
a second color compensation layer in any one of the first sub-pixel to the fourth sub-pixel in the first pixel area,
wherein the second color compensation layer is on one side of the first color compensation layer, and the second color compensation layer is continuously disposed with the first color compensation layer.

18. The transparent display device according to claim 15, further comprising:
a second color compensation layer in any one of the first sub-pixel to the fourth sub-pixel in the first pixel area; and
a third color compensation layer in any one of the first sub-pixel to the fourth sub-pixel disposed in the second pixel area,
wherein the second color compensation layer is on a first side of the first color compensation layer, and the second color compensation layer is disposed continuously with the first color compensation layer, and the third color compensation layer is on a second side of the first color compensation layer, and the third color compensation layer is disposed continuously with the first color compensation layer.

19. The transparent display device according to claim 15, further comprising:
a fourth color compensation layer in the first pixel area and the second pixel area, the fourth color compensation layer including a same material as the first color compensation layer,
wherein the fourth color compensation layer is disposed continuously with the first color compensation layer.

20. The transparent display device according to claim 19, wherein the fourth color compensation layer is in the first sub-pixel to the fourth sub-pixel in the first pixel area and the first sub-pixel to the fourth sub-pixel in the second pixel area.

21. A transparent display device comprising:
a first substrate including a display area that display an image and a transmissive area that is more transmissive of light than the display area;
a first transistor in the display area;
a first light emitting element in the display area, the first light emitting element connected to the first transistor;
a color filter in the display area, the color filter overlapping the first light emitting element; and
a first color compensation layer in the transmissive area, the first color compensation layer on a same plane as the color filter.

22. The transparent display device of claim 21, wherein the first color compensation layer has a transmittance of light in a first wavelength range from 380 nm to 500 nm that is greater than a transmittance of light in a second wavelength range from 500 nm to 780 nm,
wherein the transmittance of light in the second wavelength range is greater than or equal to 80%.

23. The transparent display device of claim 21, further comprising:
a second transistor in the display area;
a second light emitting element in the display area, the second light emitting element connected to the second transistor; and
a second color compensation layer that overlaps the second light emitting element,
wherein the second color compensation layer is on a same plane as the color filter and the first color compensation layer.

24. The transparent display device of claim 23, wherein the first color compensation layer and the second color compensation layer include a same material.

25. The transparent display device of claim 24, wherein a thickness of the first color compensation layer is a same as a thickness of the second color compensation layer.

26. The transparent display device of claim 24, wherein a thickness of the first color compensation layer is less than a thickness of the second color compensation layer.

27. The transparent display device of claim 23, further comprising:
a third color compensation layer on the color filter such that the third color compensation layer is between the color filter and the first substrate,
wherein the first color compensation layer, the second color compensation layer, and the third color compensation layer include a same material.

28. The transparent display device of claim 27, wherein a thickness of the third color compensation layer is less than a thickness of the second color compensation layer and a thickness of the first color compensation layer.

29. The transparent display device of claim 28, wherein a sum of a thickness of the color filter and the thickness of the third color compensation layer is equal to at least one of the thickness of the second color compensation layer and the thickness of the first color compensation layer.
